(19) United States
(12) Patent Application Publication
(10) Pub. No.: US 2025/0359032 A1
(43) Pub. Date: Nov. 20, 2025

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: HOIN LEE, Suwon-si (KR); HO-IN RYU, Suwon-si (KR); BYUNG-HYUN LEE, Suwon-si (KR); HOOUK LEE, Suwon-si (KR)

(73) Assignee: SAMSUNG ELECTRONICS CO., LTD., Suwon-si (KR)

(21) Appl. No.: 19/048,006

(22) Filed: Feb. 7, 2025

(30) Foreign Application Priority Data
May 14, 2024 (KR) 10-2024-0063494

(51) Int. Cl. H10B 12/00; H01L 23/528; H01L 23/532; H10D 64/66; H10D 64/68

(52) U.S. Cl. CPC H10B 12/488; H01L 23/5283; H01L 23/53295; H10B 12/0335; H10B 12/09; H10B 12/50; H10D 64/666; H10D 64/685

(57) ABSTRACT

A semiconductor device is provided. The semiconductor device includes: a substrate; a first gate insulating film on the substrate; a first gate electrode on the first gate insulating film; a first capping film on the first gate electrode; a first gate spacer in contact with the first gate insulating film, the first gate electrode, and the first capping film; an insulating liner on the first capping film and the first gate spacer; an insulating layer on at least a portion of the first gate spacer and defining a main hole; a mask layer including a base part on an upper surface of the insulating layer, and a pillar part extending into the main hole and contacting the substrate; and a plug provided in the main hole and surrounded by the pillar part of the mask layer.

### CROSS-REFERENCE TO RELATED APPLICATION

This application claims priority to Korean Patent Application No. 10-2024-0063494, filed on May 14, 2024, in the Korean Intellectual Property Office, the disclosure of which is incorporated by reference herein in its entirety.

### BACKGROUND

The present disclosure relates to a semiconductor device and a method of manufacturing the semiconductor device.

Semiconductors include tiny circuit patterns on a nanometer scale that are invisible to the naked eye. To create these tiny patterns, portions to etch and portions to retain. This process is known as photolithography in the semiconductor process. Lithography refers to a method by which a design is etched onto a stone plate and then printed. Because the design is printed, the same shape may be replicated repeatedly. In the semiconductor process, these identical shapes need to be printed without any errors even in tens of nanometers. “Photo” indicates that a lithographic technique is implemented using light. The design is etched onto a plate called a mask, and light is shone through the mask so that only the areas where light passes through are focused onto a wafer through an optical system lens, creating a small pattern printed on the wafer. The photoresist coating on the wafer undergoes a chemical reaction only in the areas exposed to light, resulting in a difference in solubility between the exposed and unexposed areas. Subsequently, the develop process allows for selective etching of the desired pattern areas in the etch process or selective injection of implants in the implant process.

Due to characteristics such as miniaturization, multifunctionality, and/or lower manufacturing costs, semiconductor devices are gaining prominence as key components in the electronics industry. However, as the electronics industry continues to highly advance, the trend towards higher integration of semiconductor devices is intensifying. To achieve higher integration, the line widths of patterns in semiconductor devices are being progressively reduced. Recently, however, the miniaturization of these patterns has required new exposure technologies and/or high-cost exposure techniques, making it increasingly challenging to achieve higher integration in semiconductor devices. Accordingly, a great deal of research is currently being conducted on new integration technologies. For example, in dynamic random-access memory (DRAM) memory devices, structures in which word lines are embedded within a semiconductor substrate are being explored.

### SUMMARY

According to an aspect of an embodiment, a semiconductor device includes: a substrate; a first gate insulating film on the substrate; a first gate electrode on the first gate insulating film; a first capping film on the first gate electrode; a first gate spacer in contact with the first gate insulating film, the first gate electrode, and the first capping film; an insulating liner on the first capping film and the first gate spacer; an insulating layer on at least a portion of the first gate spacer and defining a main hole; a mask layer including a base part on an upper surface of the insulating layer, and a pillar part extending into the main hole and contacting the substrate; and a plug provided in the main hole and surrounded by the pillar part of the mask layer.

According to an aspect of an embodiment, a method of manufacturing a semiconductor device includes: providing a structure including an insulating layer on a substrate; forming a main hole in the insulating layer; forming a mask layer in the main hole; forming a plug hole in the mask layer; and forming a plug in the plug hole.

### BRIEF DESCRIPTION OF DRAWINGS

The foregoing and other aspects and features will be more apparent from the following description of embodiments, with reference to the accompanying drawings.

FIG. 1 is a plan view schematically illustrating a partial structure of a cell array area of a semiconductor device, according to an embodiment.

FIG. 2A is a cross-sectional view of the semiconductor device taken along a line A-A′ of FIG. 1, according to an embodiment.

FIG. 2B is a cross-sectional view of the semiconductor device taken along a line B-B′ of FIG. 1, according to an embodiment.

FIG. 2C is a cross-sectional view of the semiconductor device taken along a line C-C′ of FIG. 1, according to an embodiment.

FIG. 2D is a cross-sectional view of the semiconductor device taken along a line D-D′ of FIG. 1, according to an embodiment.

FIG. 3 is a cross-sectional view of a semiconductor device according to an embodiment.

FIG. 4 is a cross-sectional view of the semiconductor device and illustrates a main hole formed in an insulating layer, according to an embodiment.

FIG. 5 is a cross-sectional view of the semiconductor device and illustrates a mask layer formed in the main hole, according to an embodiment.

FIG. 6 is a cross-sectional view of a semiconductor device and illustrates a plug hole formed in the mask layer, according to an embodiment.

FIG. 7 is a plan view schematically illustrating a plug and the mask layer, according to an embodiment.

FIG. 8 is an enlarged cross-sectional view of a portion of the semiconductor device, according to an embodiment.

FIG. 9 is a flowchart schematically illustrating a method of manufacturing a semiconductor device, according to an embodiment.

FIG. 10 is a cross-sectional view of a semiconductor device according to an embodiment.

FIG. 11 is a plan view schematically illustrating a plug and a mask layer according to an embodiment.

### DETAILED DESCRIPTION

Hereinafter, embodiments will be described in detail with reference to the accompanying drawings. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

The accompanying drawings relate to dynamic random access memory (DRAM), but the present disclosure is not limited thereto.

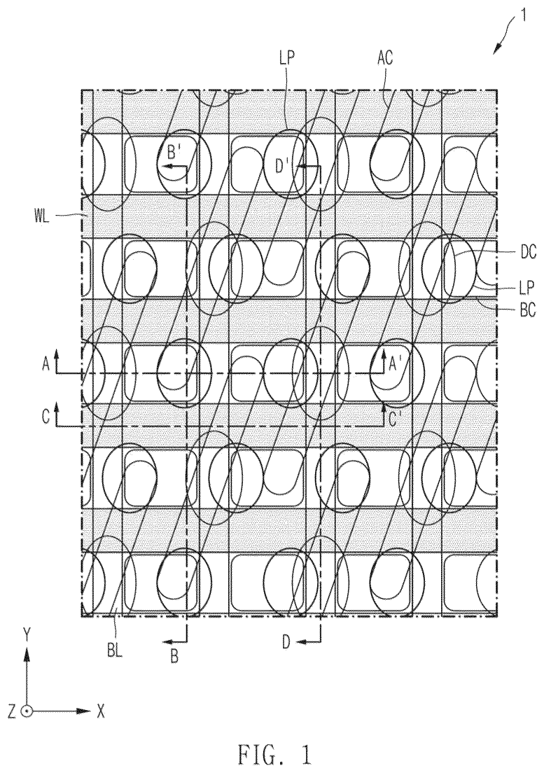

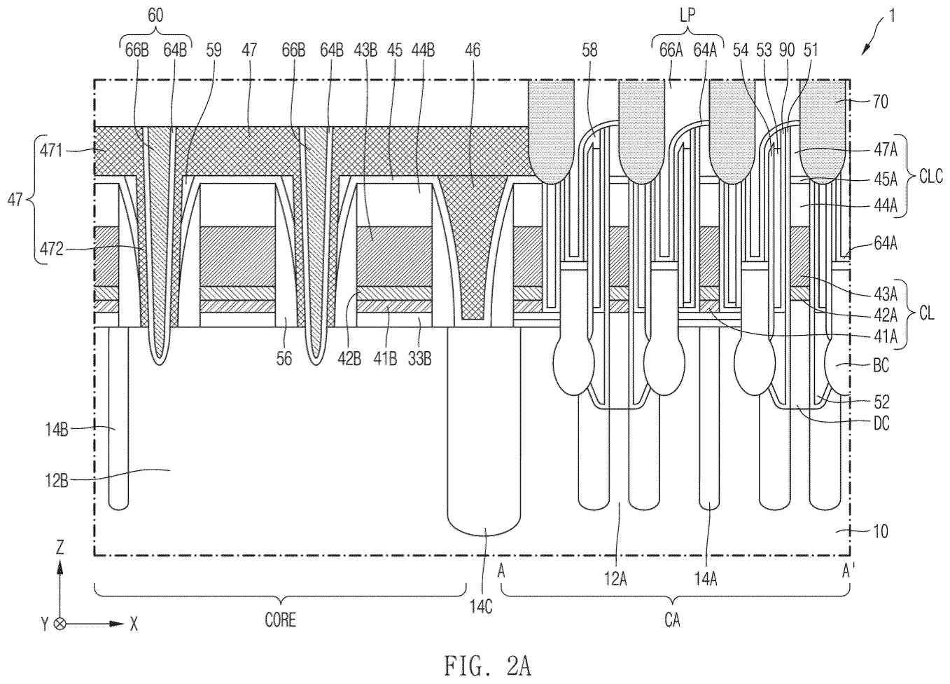

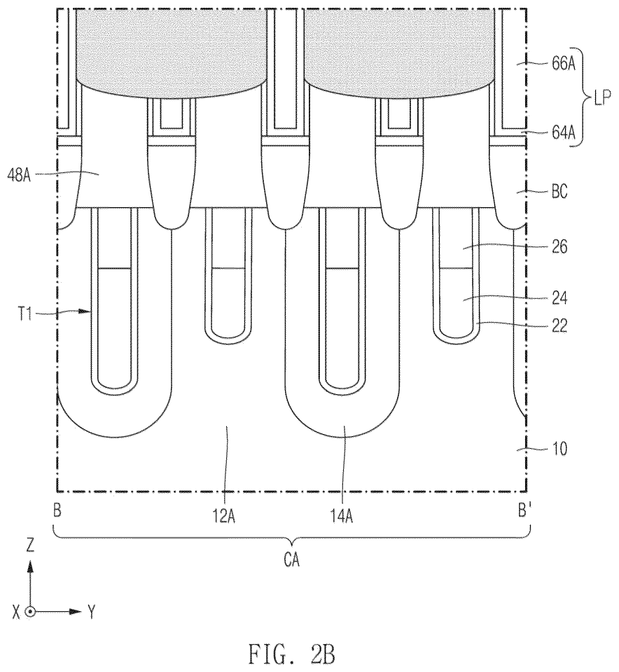

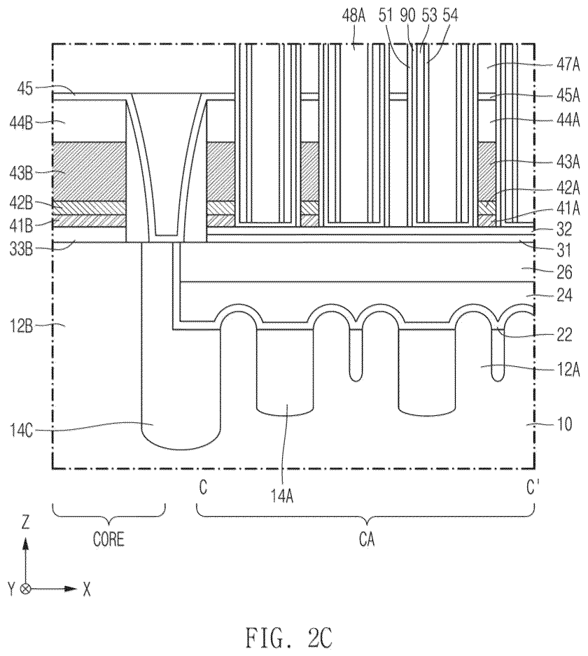

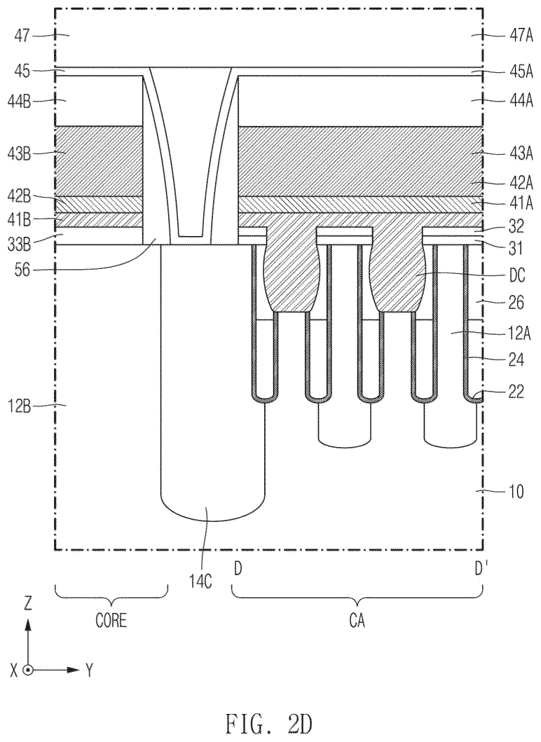

FIG. 1 is a plan view schematically illustrating a partial structure of a cell array area of a semiconductor device, according to an embodiment. FIG. 2A is a cross-sectional view of the semiconductor device taken along a line A-A′ of FIG. 1, according to an embodiment. FIG. 2B is a cross-sectional view of the semiconductor device taken along a line B-B′ of FIG. 1, according to an embodiment. FIG. 2C is a cross-sectional view of the semiconductor device taken along a line C-C′ of FIG. 1, according to an embodiment. FIG. 2D is a cross-sectional view of the semiconductor device taken along a line D-D′ of FIG. 1, according to an embodiment.

Referring to FIGS. 1 to 2D, a semiconductor device 1 may include a cell array area CA and a core area CORE. The core area CORE may be disposed around the cell array area CA.

The cell array area CA may include a plurality of active areas AC. The active areas AC may be defined by an element separating layer (e.g., element separating layer 14A of FIG. 2A) formed in a substrate (e.g., a substrate 10 of FIG. 2A). The active areas AC may be disposed in the form of a bar extending along a diagonal line or an oblique line.

A plurality of word lines WL may intersect the active areas AC to form a plurality of gate electrodes. The plurality of word lines WL may be parallel to one another and may extend in a first direction, for example, the x-axis direction. The plurality of word lines WL may be disposed at uniform intervals. The width of the plurality of word lines WL may be the same or different. The intervals between the plurality of word lines WL may be the same or different.

Each of the active areas AC may intersect two word lines WL and may be divided into three areas. The middle area of the three areas may be referred to as a bit line-connecting area. The areas positioned at both ends of the three areas may be referred to as storage element-connecting areas.

A plurality of bit lines BL may intersect the word lines WL. For example, the plurality of bit lines BL may be orthogonal to the word lines WL. Each of the bit lines BL may extend in a second direction, for example, the y-axis direction. Each of the bit lines BL may be positioned on the word lines WL. The plurality of bit lines BL may be parallel to one another at uniform intervals. As the active areas AC extend in an oblique direction, the angles formed between the word lines WL and the active areas AC may be less than 90 degrees.

The semiconductor device 1 may include various contact structures formed on the active areas AC. For example, the contact structures include a direct contact DC, a buried contact BC, a landing pad LP, and the like.

The direct contact DC may be a contact structure that electrically connects the active areas AC to the bit lines BL. The buried contact BC may be a contact structure that connects the active areas AC to a lower electrode of a capacitor. In the case of the buried contact BC, the contact area between the buried contact BC and the active areas AC may be small due to the layout structure. To increase the contact area, a conductive landing pad LP may be introduced between the active areas AC and the buried contact BC. The landing pad LP may be interposed between the buried contact BC and a lower electrode of a capacitor to expand the contact area between the lower electrode of the capacitor and the buried contact BC.

The direct contact DC may be connected to the bit line-connecting area of the active areas AC. The buried contact BC may be connected to the storage element-connecting area. The landing pad LP may be adjacent to the buried contact BC of the active areas AC. The landing pad LP may partially or entirely overlap the buried contact BC of the active areas AC. The buried contact BC may be formed to overlap the active areas AC and an element separating layer 14A positioned between adjacent word lines WL and adjacent bit lines BL. A plurality of buried contacts BC may be disposed to be spaced apart from one another in the first direction (x direction) and the second direction (y direction).

The word lines WL may be buried in the substrate 10. The word lines WL may be disposed to traverse the active areas AC between direct contacts DC or between buried contacts BC.

The direct contacts DC may be arranged symmetrically and may thus be arranged along a straight line extending in the first direction (x direction) and the second direction (y direction). The buried contacts BC may be arranged symmetrically and may thus be arranged along a straight line extending in the first direction (x direction) and along a straight line extending in the second direction (y direction). Landing pads LP may be arranged in the form of zigzags in the second direction (y direction) in which the bit lines extend. The landing pad LP may be disposed to overlap the same side portion of each of the bit lines BL in the first direction (x direction) in which the word lines WL extend. For example, each of the landing pads LP in the first column may overlap the left side of a corresponding bit line BL. Each of the landing pads LP in the second column may overlap the right side of a corresponding bit line BL.

The semiconductor device 1 may include the substrate 10. The substrate 10 may include the cell array area CA and the core area CORE that are partitioned by a cell area separating layer 14C. The cell array area CA may include an active area 12A. The core area CORE may include an active area 12B. The active area 12A may be defined by an element separating layer 14A. The active area 12B may be defined by an element separating layer 14B. As the element separating layer 14A, 14B defines the active area 12A, 12B, the element separating layer 14A, 14B may be disposed around the active area 12A, 12B.

The substrate 10 may be a silicon substrate or a silicon-on-insulator (SOI). The substrate 10 may include silicon germanium, silicon germanium on insulator (SGOI), indium antimonide, a lead telluride compound, indium arsenide, indium phosphide, gallium arsenide, or gallium antimonide, but embodiments are not limited thereto.

The element separating layer 14A, 14B and the cell area separating layer 14C may have a shallow trench isolation (STI) structure having an excellent element separating characteristic.

In the cell array area CA, a plurality of active areas 12A may have relatively long island shapes, each having a short axis and a long axis, like the active areas AC illustrated in FIG. 1.

The element separating layer 14A, 14B and the cell area separating layer 14C may include a silicon oxide, a silicon nitride, a silicon oxynitride, or a combination thereof, but embodiments are not limited thereto. In FIGS. 2A to 2D, the element separating layer 14A, 14B and the cell area separating layer 14C are illustrated as being formed as a single layer, but this is only for convenience of description, and embodiments are not limited thereto. Each of the element separating layer 14A, 14B and the cell area separating layer 14C may be formed as a single insulating layer or a plurality of insulating layers depending on the width of each of the element separating layer 14A, 14B and the cell area separating layer 14C.

In FIGS. 2A to 2D, the upper surface of each of the element separating layer 14A, 14B and the cell area separating layer 14C is illustrated as being on the same plane as the upper surface of the substrate 10, but this is only for convenience of description, and embodiments are not limited thereto.

The semiconductor device 1 may include a word line with a buried structure. A cell gate structure may include a cell gate insulating layer 22, a cell gate electrode 24, and a cell gate capping 26. The cell gate structure may be formed in the substrate 10 and the element separating layer 14A. The cell gate structure (e.g., the cell gate insulating layer 22, the cell gate electrode 24, and the cell gate capping 26) may be formed to traverse the element separating layer 14A and the active area 12A defined by the element separating layer 14A. Here, the cell gate electrode 24 may correspond to a word line WL.

Referring to FIG. 2B, the cell gate insulating layer 22 may be formed along a side wall and the bottom surface of a cell gate trench T1, and along at least a portion of a profile of the cell gate trench T1. The cell gate insulating layer 22 may include at least one of a silicon oxide, a silicon nitride, a silicon oxynitride, or a high-k dielectric material having a dielectric constant higher than the silicon oxide. The high-k dielectric material may include, for example, at least one of a hafnium oxide, a hafnium silicon oxide, a hafnium aluminum oxide, a lanthanum oxide, a lanthanum aluminum oxide, a zirconium oxide, a zirconium silicon oxide, a tantalum oxide, a titanium oxide, a barium strontium titanium oxide, a barium titanium oxide, a strontium titanium oxide, a yttrium oxide, an aluminum oxide, a lead scandium tantalum oxide, a lead zinc niobate, and a combination thereof.

The cell gate electrode 24 may be formed on the cell gate insulating layer 22. The cell gate electrode 24 may fill a portion of the cell gate trench T1.

The cell gate electrode 24 may include, for example, at least one of a metal, a metal alloy, a conductive metal nitride, a conductive metal carbonitride, a conductive metal carbide, a metal silicide, a doped semiconductor material, a conductive metal oxynitride, and a conductive metal oxide. The cell gate electrode 24 may include, for example, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx, and a combination thereof.

The cell gate capping 26 may be disposed on the cell gate electrode 24 or a cell gate capping conductive layer. The cell gate capping 26 may fill the remaining space of the cell gate trench Tl after the cell gate electrode 24 is formed. The cell gate insulating layer 22 is illustrated as being formed along a side wall of the cell gate capping 26, but embodiments are not limited thereto. The cell gate capping 26 may include, for example, at least one of a silicon nitride (SiN), a silicon oxynitride (SiON), a silicon oxide (SiO2), a silicon carbonitride (SiCN), a silicon oxycarbonitride (SiOCN), and a combination thereof.

An impurity-containing area with injected impurities may be formed on at least one side of the cell gate structure (e.g., the cell gate insulating layer 22, the cell gate electrode 24, and the cell gate capping 26). The impurity-containing area may be a source/drain area of a transistor.

In the cell array area CA, a cell conductive line CL may be disposed, and a cell line capping layer CLC may be disposed above the cell conductive line CL. The cell conductive line CL and the cell line capping layer CLC together may be referred to as a “cell line structure”. The cell conductive line CL may be formed on the element separating layer 14A and the substrate 10 on which the cell gate structure (e.g., the cell gate insulating layer 22, the cell gate electrode 24, and the cell gate capping 26) is formed. The cell conductive line CL may intersect the element separating layer 14A and the active area AC. The cell conductive line CL may be formed to intersect the cell gate structure (e.g., the cell gate insulating layer 22, the cell gate electrode 24, and the cell gate capping 26). Here, the cell conductive line CL may correspond to a bit line BL.

The cell conductive line CL may include multiple layers. The cell conductive line CL may include, for example, a first conductive layer 41A, a second conductive layer 42A, and a third conductive layer 43A. The first conductive layer 41A, the second conductive layer 42A, and the third conductive layer 43A may be sequentially stacked on the substrate 10 and the element separating layer 14A. The cell conductive line CL is not limited to a triple-layer structure.

Each of the first conductive layer 41A, the second conductive layer 42A, and the third conductive layer 43A may include, for example, at least one of a semiconductor material into which impurities are doped, a conductive silicide compound, a conductive metal nitride, a metal, and a metal alloy. For example, the first conductive layer 41A may include a doped semiconductor material (e.g., doped polysilicon, etc.), the second conductive layer 42A may include at least one of a conductive silicide compound and a conductive metal compound, and the third conductive layer 43A may include at least one of a metal and a metal alloy. However, embodiments are not limited thereto.

A direct contact DC may electrically connect the cell conductive line CL to the substrate 10. The direct contact DC may be disposed at a point at which the cell conductive line CL intersects with the middle portion of a long island-shaped active area AC. The direct contact DC may be formed on the bit line-connecting area of the active area AC.

Referring to FIG. 2A, at a point at which the cell conductive line CL intersects with the active area 12A of the substrate 10, the lower surface of the cell conductive line CL may be in contact with the active area 12A. The lower surface of the cell conductive line CL extending to the active area 12A of the substrate 10 may act as a direct contact DC. In some embodiments, the first conductive layer 41A of the cell conductive line CL that is in contact with the active area 12A may act as a direct contact DC.

The cell line capping layer CLC may be disposed on the cell conductive line CL. The cell line capping layer CLC may extend in the second direction (y direction) along the upper surface of the cell conductive line CL.

The cell line capping layer CLC may include, for example, at least one of a silicon nitride, a silicon oxynitride, a silicon carbonitride, and a silicon oxycarbonitride.

As illustrated, the cell line capping layer CLC may have a triple-layer structure. For example, the cell line capping layer CLC may include a cell line capping 44A, a cell line insulating layer 45A, and a first mask layer 47A.

The cell line capping 44A, the cell line insulating layer 45A, and the first mask layer 47A may include, for example, at least one of a silicon nitride, a silicon oxynitride, a silicon carbonitride, and a silicon oxycarbonitride.

In FIGS. 2A to 2D, the cell line capping layer CLC is illustrated as having a triple-layer structure, but embodiments are not limited thereto. For example, the cell line capping layer CLC may have a single-layer, a double-layer, or a structure with four or more layers.

A cell insulating film (e.g., a first insulating film 31 and a second insulating film 32) may be formed on the substrate 10 and the element separating layer 14A. More particularly, the cell insulating film (e.g., 31 and 32) may be formed on an area of the substrate 10 offset from each of a direct contact DC, a buried contact BC, the element separating layer 14A, and the cell area separating layer 14C. The cell insulating film may be formed between the substrate 10 and the cell conductive line CL, and between the element separating layer 14A and the cell conductive line CL.

The cell insulating film may be a single film but may also be multiple films including the first insulating film 31 and the second insulating film 32 as illustrated. For example, the first insulating film 31 may include a silicon oxide film and the second insulating film 32 may include a silicon nitride film, but embodiments are not limited thereto. For example, the cell insulating film may be a triple-layer film including a silicon oxide film, a silicon nitride film, and a silicon oxide film, but embodiments are not limited thereto.

A cell line spacer (e.g., a first spacer 51, a second spacer 52, a third spacer 53, a fourth spacer 54, and a reinforcing spacer 90) may be disposed at a side wall of a cell line structure. In a portion of the cell conductive line CL including a direct contact DC, the cell line spacer (e.g., the first spacer 51, the second spacer 52, the third spacer 53, the fourth spacer 54, and the reinforcing spacer 90) may be formed on the substrate 10 and the element separating layer 14A.

In the remaining portion of the cell conductive line CL in which the direct contact DC is not formed, the cell line spacer may be disposed on the cell insulating film (e.g., 31 and 32).

The cell line spacer may include a plurality of spacers of two or more types. In embodiments, the cell line spacer may include a plurality of spacers. The plurality of spacers may include, for example, at least one of a silicon oxide, a silicon nitride, a silicon oxynitride (SiON), a silicon oxycarbonitride (SiOCN), air, and a combination thereof. However, embodiments are not limited thereto.

Referring to FIG. 2A, the cell line spacer may include the first spacer 51, the second spacer 52, the third spacer 53, the fourth spacer 54, and the reinforcing spacer 90.

The first spacer 51 may cover the both side walls of the cell line structure, the inner wall of a direct contact hole (DCH), and the upper surface of the second insulating film 32.

The second spacer 52 may fill the DCH that is not filled by the first spacer 51.

The reinforcing spacer 90 may be positioned above the second spacer 52 and cover and reinforce a side wall of the first spacer 51 formed on both side walls of the cell line structure.

The third spacer 53 may cover a side wall of the reinforcing spacer 90 formed on a side wall of the cell line structure and include air according to this embodiment.

The fourth spacer 54 may cover a side surface of the third spacer 53 and a side surface of a buried contact BC, which are formed on both side walls of the cell line structure.

The first spacer 51, the second spacer 52, the fourth spacer 54, and the reinforcing spacer 90 may include a silicon nitride, but embodiments are not limited thereto.

Referring to FIG. 2B, a partition wall 48A may be disposed on the substrate 10 and the element separating layer 14A. The partition wall 48A may be formed to overlap the cell gate structure (e.g., the cell gate insulating layer 22, the cell gate electrode 24, and the cell gate capping 26) formed in the substrate 10 and the element separating layer 14A. The partition wall 48A may be disposed between cell line structures extending in the second direction (y direction). The partition wall 48A may include, for example, at least one of a silicon oxide, a silicon nitride, a silicon oxynitride, and a combination thereof, but embodiments are not limited thereto.

At least a portion of a buried contact BC may be buried in a substrate. The lower surface of the buried contact BC may be lower than the upper surface of the substrate 10. As illustrated in FIG. 2A, the upper surface of the buried contact BC may be higher than the upper surface of the substrate 10, but embodiments are not limited thereto.

The buried contact BC may be disposed between the cell conductive line CL adjacent to the buried contact BC in the first direction (x direction). The buried contact BC may be disposed between the partition wall 48A adjacent to the buried contact BC in the second direction (y direction). The buried contact BC may overlap the substrate 10 and the element separating layer 14A between adjacent cell conductive lines CL. The buried contact BC may be connected to the storage element-connecting area of the active area AC.

The buried contact BC may include, for example, at least one of a semiconductor material into which impurities are doped, a conductive silicide compound, a conductive metal nitride, and a metal. The buried contact BC may include, for example, doped polysilicon as the semiconductor material into which impurities are doped. The buried contact BC may include polysilicon doped with, for example, phosphorus, arsenic, boron, or a combination thereof.

A cell spacer 58 may be disposed to cover the side wall of the cell line spacers on both side walls of the cell line structure and the side wall of the partition wall 48A in contact with the landing pad LP. Referring to FIG. 2A, in some embodiments, when a portion of the cell line spacer is etched in the process of forming a buried contact hole (BCH), the cell spacer 58 may be formed to cover the upper portion of the cell line spacer positioned lower than the cell line capping layer CLC.

As described below, the cell spacer 58 formed in the cell array area CA may be formed before a plug hole CPH is formed. A plug spacer 59 and the cell spacer 58 may be formed at different times. Accordingly, the cell spacer 58 may be formed to be thin, and the plug spacer 59 may be formed to be thick to secure a sufficient spacing distance from a core gate structure. A thickness may be a width in a direction horizontal to the substrate 10.

The landing pad LP may be formed on the buried contact BC. The landing pad LP may be electrically connected to the buried contact BC. The landing pad LP may be connected to the storage element-connecting area of the active area AC.

The landing pad LP may overlap a portion of the upper surface of the cell line structure.

Referring to FIG. 2A, the landing pad LP may include a first conductive barrier layer 64A and a seventh conductive layer 66A. The first conductive barrier layer 64A may have, for example, a stacked structure of Ti, TiN, or Ti/TiN. The seventh conductive layer 66A may include, for example, at least one of a semiconductor material into which impurities are doped, a conductive silicide compound, a conductive metal nitride, a conductive metal carbide, a metal, and a metal alloy.

A pad separating insulating layer 70 may be formed on the landing pad LP and the cell line structure. For example, the pad separating insulating layer 70 may be disposed on the cell line capping layer CLC. The pad separating insulating layer 70 may define the landing pad LP forming a plurality of isolated areas. The pad separating insulating layer 70 may not cover the upper surface of the landing pad LP. The pad separating insulating layer 70 may separate an adjacent landing pad LP. For example, based on the upper surface of the substrate 10, the height of the upper surface of the landing pad LP may be the same as the height of the upper surface of the pad separating insulating layer 70.

The pad separating insulating layer 70 may include an insulating material and electrically separate a plurality of landing pads LP from one another. For example, the pad separating insulating layer 70 may include at least one of a silicon oxide, a silicon nitride, a silicon oxynitride, a silicon oxycarbonitride, and a silicon carbonitride.

Referring to FIG. 2A, the element separating layer 14B may be formed in the substrate 10 of the core area CORE. The element separating layer 14B may define the active area 12B in the core area CORE. The upper surface of the element separating layer 14B is illustrated as being on the same plane as the upper surface of the substrate 10, but embodiments are not limited thereto.

The core gate structure may be disposed on the substrate 10 of the core area CORE. The core gate structure may be disposed on the active area 12B defined by the element separating layer 14B.

The core gate structure may include a gate insulating film 33B, a gate electrode (e.g., a fourth conductive layer 41B, a fifth conductive layer 42B, and a sixth conductive layer 43B), and a capping film 44B, which are sequentially stacked on the substrate 10. The core gate structure may include a gate spacer 56 disposed on a side wall of the gate electrode (e.g., 41B, 42B, and 43B) and a side wall of the capping film 44B.

The gate electrode may include the fourth conductive layer 41B, the fifth conductive layer 42B, and the sixth conductive layer 43B, which are sequentially stacked on the gate insulating film 33B. For example, an additional conductive layer may not be disposed between the gate electrode and the gate insulating film 33B. In another example, For example, an additional conductive layer such as a work function conductive layer may be disposed between the gate electrode and the gate insulating film 33B.

Although it is illustrated that two core gate structures are disposed between adjacent element separating layers 14B, this is only for convenience of description, and embodiments are not limited thereto.

An insulating liner 45 may be disposed on the substrate 10. The insulating liner 45 may be formed along a profile of the core gate structure. The insulating liner 45 may also be formed on first and second insulating films 31 and 32 remaining after a cell conductive line is etched on the cell area separating layer 14C, first to third conductive layers, and an etched side wall and the upper surface of a capping layer. In this case, the gate spacer 56 formed during the process of forming the gate spacer 56 may be interposed between the insulating liner 45 and the first and second insulating films 31 and 32, the third to third conductive layers, and the etched side wall of the capping layer.

The insulating liner 45 may include at least one of a silicon nitride, a silicon oxynitride, a silicon carbonitride, and a silicon oxycarbonitride.

An insulating layer 46 may be formed between a plurality of core gate structures. According to some embodiments, when the insulating liner 45 is formed, the insulating layer 46 may be disposed on the insulating liner 45. The insulating layer 46 may also be formed on the cell area separating layer 14C.

The insulating layer 46 may be formed of an insulating material with an excellent gap fill characteristic. The insulating layer 46 may include an oxide. The insulating layer 46 may be formed of, for example, a boron-phosphor silicate glass (BPSG) film, a high density plasma (HDP) oxide film, a O3-TEOS film, undoped silicate glass (USG), or a tonen silazene (TOSZ) material. The insulating layer 46 may include a silicon oxide formed of a TOSZ material.

The upper surface of the insulating layer 46 may be on the same plane as the insulating liner 45 along the upper surface of the core gate structure, but embodiments are not limited thereto. According to some embodiments, when the insulating liner 45 is not formed, the upper surface of the insulating layer 46 may be on the same plane as the upper surface of the core gate structure.

A mask layer 47 may be disposed on the core gate structure and the insulating layer 46. The mask layer 47 may include a base part 471 disposed on the upper side of the insulating layer 46 and a pillar part 472 inserted into a main hole provided in the insulating layer 46 and in contact with a substrate. A portion of the pillar part 472 may be provided in a state of being inserted into the substrate 10. The pillar part 472 may enclose a plug 60. The pillar part 472 of the mask layer 47 may be provided between the plug 60 and the gate spacer 56 to prevent the plug 60 and the gate spacer 56 from touching each other. The mask layer 47 may protect the insulating layer 46 from the plug 60. The mask layer 47 may cover both a side surface and the upper surface of the gate spacer 56. The mask layer 47 may overlap the gate spacer 56 in the z-axis direction. At the same time, the mask layer 47 may overlap the gate spacer 56 in the x-axis direction.

According to some embodiments, when the insulating liner 45 is formed, the mask layer 47 may cover the insulating layer 46 and the insulating liner 45 extending along the upper surface of the core gate structure.

The height of the upper surface of the mask layer 47 may be the same as the height of the upper surface of the cell line capping layer CLC, based on the upper surface of the substrate 10.

The mask layer 47 may include a material different from the insulating layer 46. For example, when the insulating layer 46 includes a silicon oxide, the mask layer 47 may include at least one of a silicon nitride, a silicon oxynitride, a silicon carbonitride, and a silicon oxycarbonitride, but embodiments are not limited thereto.

The plug 60 may be disposed on both sides of the core gate structure. The plug 60 may pass through the mask layer 47 and the insulating layer 46 and extend to the substrate 10 of the core area CORE. The plug may be in contact with the substrate 10 of the core area CORE. A wiring line may be disposed on the mask layer 47. The plug and the wiring line may be separated by a wiring separating recess.

As the plug 60 and the landing pad LP are formed at the same time, the plug may include the same material as the landing pad LP.

The plug 60 may include a second conductive barrier layer 64B and an eighth conductive layer 66B. The second conductive barrier layer 64B may be formed simultaneously with the first conductive barrier layer 64A of the landing pad LP and may thus include the same material. The eighth conductive layer 66B may be formed simultaneously with the seventh conductive layer 66A of the landing pad LP and may thus include the same material.

Referring to FIG. 2A, the plug spacer 59 may not be disposed on the lower surface of the plug 60 but may be disposed on a side wall of the plug 60. The plug spacer 59 may include, for example, at least one of a silicon nitride, a silicon oxynitride, a silicon carbonitride, and a silicon oxycarbonitride.

The plug spacer 59 may be applied to any plug in the core area CORE. However, embodiments are not limited thereto, and the plug spacer 59 may be disposed only on a side wall of some plugs 60 in the core area CORE.

The plug spacer 59 may be particularly useful in the semiconductor device 1, which is highly scaled, by increasing the separation distance between the plug 60 and the core gate structure. When a hole for forming a plug is formed to be larger than the desired size, the plug spacer 59 may be used to control the size of the plug hole. Accordingly, the aspect ratio of the plug hole to be patterned is reduced, which has the advantage of lessening the burden of the patterning process.

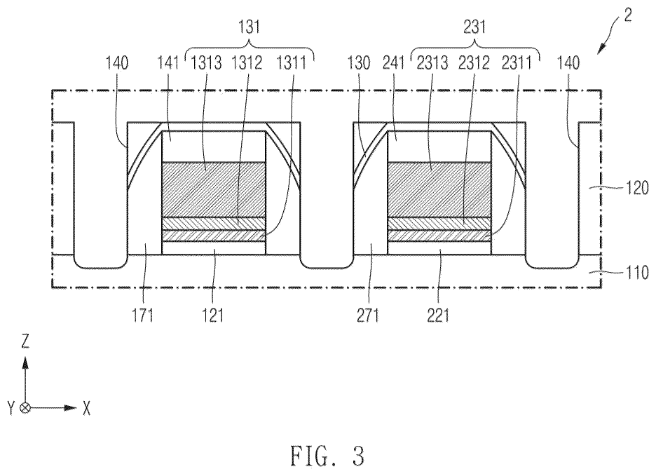

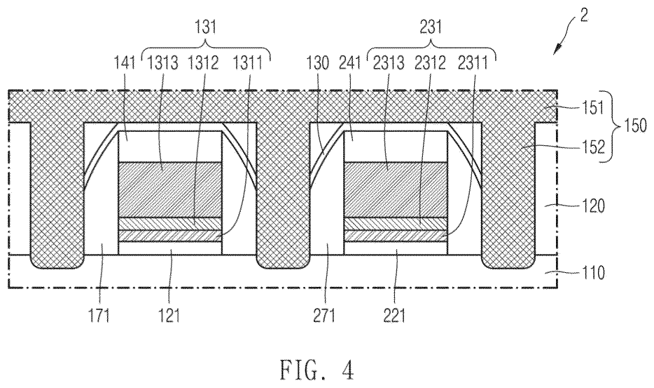

FIG. 3 is a cross-sectional view of a semiconductor device according to an embodiment. FIG. 4 is a cross-sectional view of the semiconductor device and illustrates a main hole formed in an insulating layer, according to an embodiment. FIG. 5 is a cross-sectional view of the semiconductor device and illustrates a mask layer formed in a main hole, according to an embodiment.

Referring to FIGS. 3 to 5, a semiconductor device 2 may include a substrate 110 (e.g., the substrate 10 of FIG. 2A), a first gate insulating film 121 (e.g., the gate insulating film 33B of FIG. 2A), a first gate electrode 131, a first capping film 141 (e.g., the capping film 44B of FIG. 2A), a first gate spacer 171 (e.g., the gate spacer 56 of FIG. 2A), a second gate insulating film 221, a second gate electrode 231, a second capping film 241, a second gate spacer 271, an insulating layer 120, an insulating liner (e.g., the insulating liner 130 of FIG. 2A), and a mask layer 150. The first gate electrode 131 may include a first high-k dielectric film 1311 (e.g., the fourth conductive layer 41B of FIG. 2A), a first metal film 1312 (e.g., the fifth conductive layer 42B of FIG. 2A), and a first conductive film 1313 (e.g., the sixth conductive layer 43B of FIG. 2A). The second gate electrode 231 may include a second high-k dielectric film 2311, a second metal film 2312, and a second conductive film 2313.

The substrate 110 may be a silicon substrate or may include another material such as silicon germanium, indium antimonide, a lead telluride compound, indium arsenide, indium phosphide, gallium arsenide, or gallium antimonide. The substrate 110 may be a base substrate on which an epi-layer is formed.

The first gate insulating film 121 may be disposed on the substrate 110. The first gate insulating film 121 may be disposed on the upper surface of the substrate 110. The second gate insulating film 221 may be disposed on the substrate 110. The second gate insulating film 221 may be disposed on the upper surface of the substrate 110. The first gate insulating film 121 and the second gate insulating film 221 may be disposed to be spaced apart from each other.

The first gate electrode 131 may be disposed on the first gate insulating film 121. The second gate electrode 231 may be disposed on the second gate insulating film 221.

The first capping film 141 may be disposed on the first gate electrode 131. The second capping film 241 may be disposed on the second gate electrode 231.

The first gate spacer 171 may be provided in contact with the first gate insulating film 121, the first gate electrode 131, and the first capping film 141. The first gate spacer 171 may enclose the first gate insulating film 121, the first gate electrode 131, and the first capping film 141. The second gate spacer 271 may be provided in contact with the second gate insulating film 221, the second gate electrode 231, and the second capping film 241. The second gate spacer 271 may enclose the second gate insulating film 221, the second gate electrode 231, and the second capping film 241.

The insulating layer 120 may cover at least a portion of the first gate spacer 171. The insulating layer 120 may include a main hole 140. For example, the main hole 140 may be defined in the insulating layer 120 and the substrate 110. The main hole 140 may have a pillar shape with its longitudinal direction along the z-axis direction. A plurality of main holes 140 may be provided. The plurality of main holes 140 may be provided to be spaced apart from each other on an xy plane. The main hole 140 may be recessed downward from the upper surface of the insulating layer 120. Referring FIG. 5, when the mask layer 150 is not filled, the main hole 140 may expose the substrate 110. The insulating layer 120 may include an oxide. The plurality of main holes 140 may be provided, and the pillar part of the mask layer 150 may be inserted into all of the plurality of main holes 140.

The mask layer 150 may include a base part 151 disposed on the upper side of the insulating layer 120, and a pillar part 152 inserted into the main hole 140 and in contact with the substrate 110. The mask layer 150 may include at least one of a silicon nitride, a silicon oxynitride, a silicon carbonitride, and a silicon oxycarbonitride. The pillar part 152 may enclose a plug to be described below. The pillar part 152 may have, for example, a cylindrical shape having a hollow inside. However, the shape of the pillar part 152 is not limited thereto.

The mask layer 150 may have a base part and a pillar part formed simultaneously by injecting a mask layer material into the main hole 140 and providing the mask layer material on the upper surface of the insulating layer 120 at the same time.

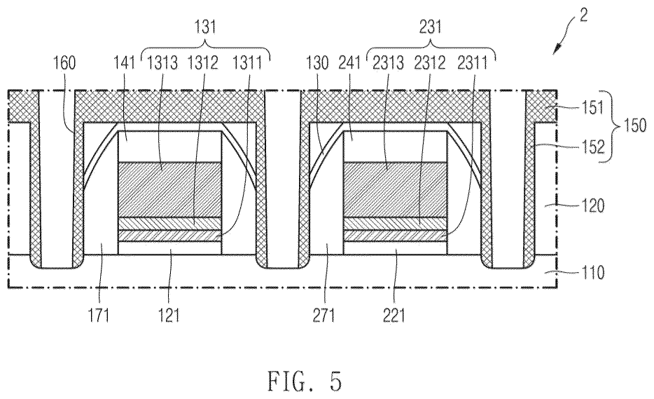

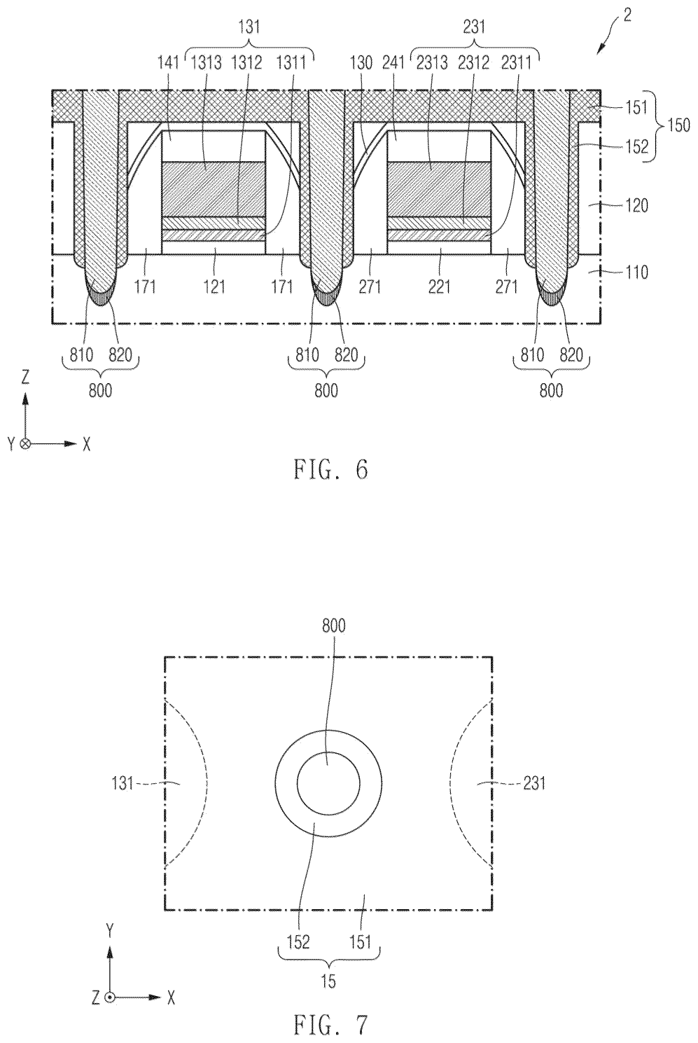

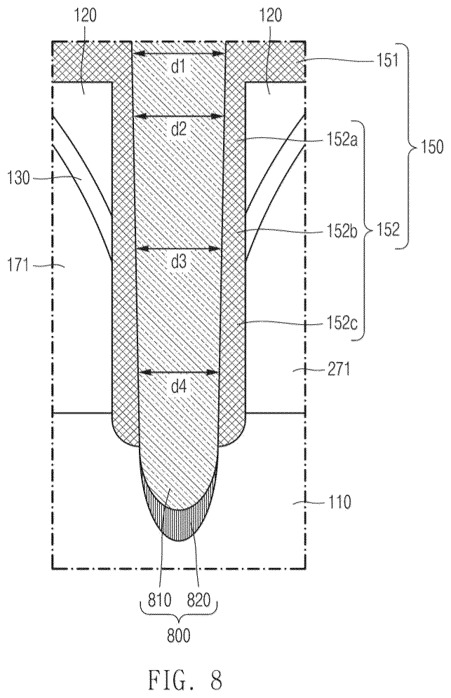

FIG. 5 is a cross-sectional view of a semiconductor device according to an embodiment and illustrates a plug hole formed in a mask layer. FIG. 6 is a cross-sectional view of a semiconductor device according to an embodiment and illustrates a plug provided in a plug hole formed in a mask layer. FIG. 7 is a plan view schematically illustrating a plug and a mask layer, according to an embodiment. FIG. 8 is an enlarged cross-sectional view of a portion of the semiconductor device, according to an embodiment.

Referring to FIGS. 6 to 8, the semiconductor device 2 may include the substrate 110, the first gate insulating film 121, the first gate electrode 131, the first capping film 141, the first gate spacer 171, the second gate insulating film 221, the second gate electrode 231, the second capping film 241, the second gate spacer 271, the insulating layer 120, the mask layer 150, and a plug 800. The first gate electrode 131 may include the first high-k dielectric film 1311, the first metal film 1312, and the first conductive film 1313. The second gate electrode 231 may include the second high-k dielectric film 2311, the second metal film 2312, and the second conductive film 2313.

A portion of the mask layer 150 may be removed. A portion of the mask layer 150 in which the pillar part 152 is formed may be removed. A plug hole 160 may be formed in the pillar part 152. The plug hole 160 may correspond to a space in which the plug 800 is provided. As the plug 800 is formed in the plug hole 160, the plug 800 may be surrounded by the pillar part 152.

The plug 800 may be provided to be spaced apart from the first gate spacer 171. The mask layer 150 may be provided to prevent the plug 800 from being in contact with the first gate spacer 171.

The plug 800 may be disposed between the first gate electrode 131 and the second gate electrode 231. The mask layer 150 may cover a side surface and the upper surface of the first gate spacer 171 simultaneously. A portion of the mask layer 150 may be inserted into the substrate 110. The pillar part 152 of the mask layer 150 may be positioned between the plug 800 and the first gate spacer 171 and provided to prevent the plug 800 from being in contact with the first gate spacer 171.

The longitudinal direction of the plug 800 may be in the z-axis direction. A plurality of plugs 800 may be provided. The plurality of plugs 800 may be provided to be spaced apart from one another in the xy plane.

The plug 800 may have a shape with a diameter decreasing toward the substrate 110. The pillar part 152 may include a first part 152a connected to the base part 151 and provided in contact with the insulating layer 120, a second part 152b connected to the first part 152a and provided in contact with the insulating liner 130, and a third part 152c connected to the second part 152b and provided in contact with the first gate spacer 171 and the second gate spacer 172. A portion of the plug 800 surrounded by the base part 151 may have a first diameter d1. A portion of the plug 800 surrounded by the insulating layer 120 may have a second diameter d2. A portion of the plug 800 surrounded by the insulating liner 130 may have a third diameter d3. A portion of the plug 800 between the first gate spacer 171 and the second gate spacer 172 may have a fourth diameter d4. The second diameter d2 may be less than or equal to the first diameter d1. The third diameter d3 may be less than or equal to the second diameter d2. The fourth diameter d4 may be less than or equal to the third diameter d3. The first part 152a of the pillar part 152 may be narrower than the second part 152b of the pillar part. The second part 152b of the pillar part 152 may be narrower than the third part 152c of the pillar part. The pillar part 152 may prevent the plug 800 from being in contact with the insulating layer 120 such that the plug 800 does not deform the insulating layer 120.

The plug 800 may include a plug body 810 surrounded by the mask layer 150 and a plug head 820 connected to an end of the plug body 810 and provided in a state of being inserted into the substrate 110. The plug body 810 may include a metal. The plug head 820 may include silicon dioxide.

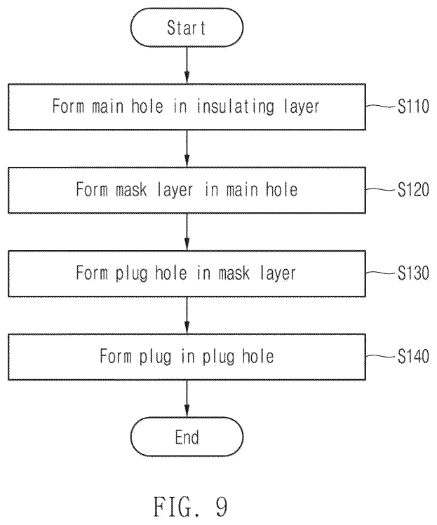

FIG. 9 is a flowchart schematically illustrating a method of manufacturing a semiconductor device, according to an embodiment.

Referring to FIG. 9, the method of manufacturing a semiconductor device may include operation S110 of forming a main hole in an insulating layer, operation S120 of introducing a mask layer in the main hole, operation S130 of curing the mask layer introduced in the main hole, operation S140 of forming a plug hole in the mask layer, and operation S150 of inputting a plug into the plug hole.

In operation S110, the main hole may be formed in the insulating layer. For example, in operation S110, the insulating layer and at least a portion of a gate spacer may be removed. In operation S110, a portion of a substrate may be exposed to the outside through the main hole. In operation S110, an insulating liner and a portion of the gate spacer may be removed together with the insulating layer.

In operation S120, the mask layer may be formed in the main hole. For example, operation S120 may be performed simultaneously in the process in which the mask layer is formed on the upper surface of the insulating layer. A base part and a pillar part of the mask layer may be formed simultaneously. The process of forming the mask layer may be implemented compactly.

In operation S130, the plug hole may be formed in the mask layer.

In operation S140, the plug may be formed in the plug hole. The plug may be surrounded by the mask layer.

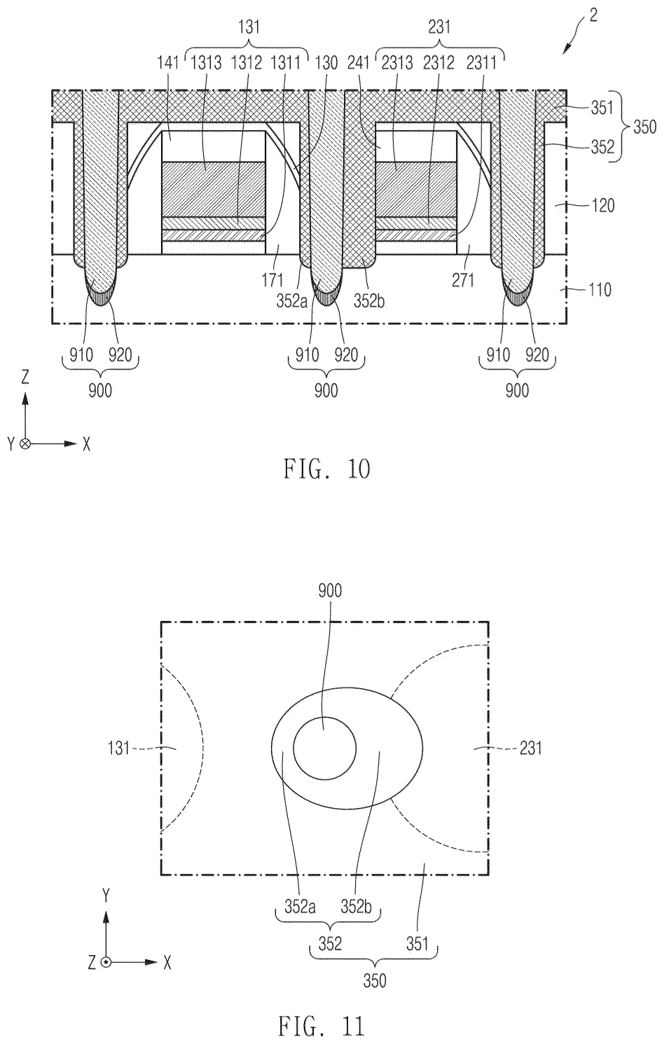

FIG. 10 is a cross-sectional view of a semiconductor device according to an embodiment. FIG. 11 is a plan view schematically illustrating a plug and a mask layer, according to an embodiment.

Referring to FIGS. 10 and 11, a semiconductor device 3 may include the substrate 110, the first gate insulating film 121, the first gate electrode 131, the first capping film 141, the first gate spacer 171, the second gate insulating film 233, the second gate electrode 231, the second capping film 241, the second gate spacer 271, the insulating layer 120, the insulating liner 130, the mask layer 150, and a plug 900. The first gate electrode 131 may include the first high-k dielectric film 1311, the first metal film 1312, and the first conductive film 1313. The second gate electrode 231 may include the second high-k dielectric film 2311, the second metal film 2312, and the second conductive film 2313.

The plug 900 may include a plug body 910 and a plug head 920. The plug 900 may be provided in a state of being surrounded by the mask layer 350. The mask layer 350 may be in contact with the first gate spacer 171. The mask layer 150 may be in contact with the second gate insulating film 233, the second gate electrode 231, and the second capping film 241.

The longitudinal direction of the plug 900 may be in the z-axis direction. A plurality of plugs 900 may be provided. The plurality of plugs 900 may be provided to be spaced apart from one another on the xy plane.

Based on the plug 900, the thickness of a portion 352b of the pillar part 352 of the mask layer 305 on the side of the second gate electrode 231 may be formed to be greater than the thickness of a portion 352a of the pillar part 352 of the mask layer 350 at the second gate electrode 231. The minimum distance from the plug 900 to the second gate electrode 231 may be greater than the minimum distance from the plug 900 to the first gate spacer 171. According to this structure, the distance between the plug 900 and the second gate electrode 231 may be sufficiently secured.

While aspects of embodiments have been particularly shown and described, it will be understood that various changes in form and details may be made therein without departing from the spirit and scope of the following claims.

What is claimed is:

1. A semiconductor device comprising:
a substrate;
a first gate insulating film on the substrate;
a first gate electrode on the first gate insulating film;
a first capping film on the first gate electrode;
a first gate spacer in contact with the first gate insulating film, the first gate electrode, and the first capping film;
an insulating liner on the first capping film and the first gate spacer;
an insulating layer on at least a portion of the first gate spacer and defining a main hole;
a mask layer comprising a base part on an upper surface of the insulating layer, and a pillar part extending into the main hole and contacting the substrate; and
a plug provided in the main hole and surrounded by the pillar part of the mask layer.

2. The semiconductor device of claim 1, wherein the plug is spaced apart from the first gate spacer.

3. The semiconductor device of claim 1, wherein the pillar part of the mask layer is between the plug and the first gate spacer to prevent the plug from contacting the first gate spacer.

4. The semiconductor device of claim 1, wherein the insulating layer comprises an oxide, and
wherein the mask layer comprises at least one of a silicon nitride, a silicon oxynitride, a silicon carbonitride, and a silicon oxycarbonitride.

5. The semiconductor device of claim 1, wherein a diameter of the plug decreases toward the substrate.

6. The semiconductor device of claim 1, wherein the pillar part comprises:
a first part connected to the base part and in contact with the insulating layer;
a second part connected to the first part and in contact with the insulating liner; and
a third part connected to the second part and in contact with the first gate spacer.

7. The semiconductor device of claim 6, wherein a diameter of a portion of the plug surrounded by the second part is less than a diameter of a portion of the plug surrounded by the first part.

8. The semiconductor device of claim 6, wherein a diameter of a portion of the plug surrounded by the third part is less than a diameter of a portion of the plug surrounded by the second part.

9. The semiconductor device of claim 1, wherein the mask layer is on a side surface and an upper surface of the first gate spacer.

10. The semiconductor device of claim 1, further comprising:
a second gate insulating film on the substrate;
a second gate electrode on the second gate insulating film;
a second capping film on the second gate electrode; and
a second gate spacer in contact with the second gate insulating film, the second gate electrode, and the second capping film.

11. The semiconductor device of claim 10, wherein the pillar part of the mask layer is between the plug and the first gate spacer to prevent the plug from contacting the first gate spacer and the second gate spacer.

12. The semiconductor device of claim 1, further comprising:
a second gate insulating film on the substrate;
a second gate electrode on the second gate insulating film; and
a second capping film on the second gate electrode,
wherein the pillar part of the mask layer is in contact with the second gate insulating film, the second gate electrode, and the second capping film.

13. The semiconductor device of claim 12, wherein a thickness of a portion of the pillar part of the mask layer on a side of the second gate electrode is greater than a thickness of a portion of the pillar part of the mask layer on a side of the first gate electrode.

14. The semiconductor device of claim 12, wherein a minimum distance between the plug and the second gate electrode is greater than a minimum distance between the plug and the first gate spacer.

15. The semiconductor device of claim 14, wherein the pillar part of the mask layer prevents the plug from contacting the second gate insulating film, the second gate electrode, and the second capping film.

16. A method of manufacturing a semiconductor device, the method comprising:
providing a structure comprising an insulating layer;
forming a main hole in the insulating layer;
forming a mask layer in the main hole;
forming a plug hole in the mask layer; and
forming a plug in the plug hole.

17. The method of claim 16, wherein the forming of the main hole comprises removing an insulating liner and a portion of a gate spacer.

18. The method of claim 16, wherein the plug is spaced apart from a gate spacer.

19. The method of claim 16, wherein at least a portion of the mask layer is provided between the plug and a gate spacer.

20. The method of claim 16, wherein the insulating layer comprises an oxide, and
wherein the mask layer comprises at least one of a silicon nitride, a silicon oxynitride, a silicon carbonitride, and a silicon oxycarbonitride.
